(19) United States
(12) Patent Application Publication
(10) Pub. No.: US 2009/0261463 A1
(43) Pub. Date: Oct. 22, 2009

(54) Chip mounting device and chip package array

(76) Inventors: Chin-Ti Chen, Hsinchu (TW); Chin-Fa Wang, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/155,350

(22) Filed: Jun. 3, 2008

(30) Foreign Application Priority Data
Apr. 16, 2008 (TW) 97113835

(51) Int. Cl. H01L 23/495

(52) U.S. Cl. 257/676; 257/E23.031

(57) ABSTRACT

A chip mounting device includes at least one chip mounting unit and at least one side rail configured beside the chip mounting unit. The chip mounting unit includes a die pad and a plurality of conductive contacts. The side rail includes at least one identifying element. A chip package array with the above-mentioned chip mounting device is also disclosed. The chip mounting device and chip package array includes the identifying element configured on the side rail to improve the identification of semi-finished packaged chips during chip package process to be read automatically by machines instead of operators, and further decrease the loss caused by misjudgments of operators.

### BACKGROUND OF THE INVENTION

1. Field of the Invention

The present invention relates to a chip mounting device and a chip package array, more particularly to a chip mounting device and a chip package array for automatic identification.

2. Description of the Prior Art

There are many forms of chip package with various package techniques and materials, depending on various factors such as chip design, electrical properties, thermal conductivity, requirement of clients and reliability, product specification, manufacturing cost, and so on. Therefore there are diversified forms of chip package.

In the conventional package process, to distinguish the subsequent package process of semi-finished packaged chips relies on checking the production process records manually by operators to know the package process of current batch. Due to the complicated chip package process, sometimes errors caused by the misjudgment of operators occur; therefore great loss is caused because chips are of high value and large production batch.

To sum up, how to improve the identification of semi-finished packaged ships during chip package process is a current goal to be achieved.

### SUMMARY OF THE INVENTION

To solve the above-mentioned problems, one objective of the present invention is to provide a chip mounting device and a chip package array for improving the identification of semi-finished packaged chips during chip package process to be read automatically by machines instead of operators, and further decrease the loss caused by misjudgments of operators.

To achieve the aforesaid objective, a chip mounting device in one preferred embodiment of the present invention includes at least one chip mounting unit and at least one side rail configured beside the chip mounting unit. The chip mounting unit includes a die pad and a plurality of conductive contacts. The side rail includes at least one identifying element.

To achieve the aforesaid objective, a chip package array in another embodiment of the present invention includes a chip mounting device and at least one chip. The chip mounting device includes at least one chip mounting unit and at least one side rail configured beside the chip mounting unit. The chip mounting unit includes a die pad and a plurality of conductive contacts. The side rail includes at least one identifying element. The chip is mounted on the die pad and electrically connected to the conductive contacts.

Other advantages of the present invention will become apparent from the following description taken in conjunction with the accompanying drawings, which are set forth by way of illustration and example, to certainly embody the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a top view showing a chip mounting device according to a preferred embodiment of the present invention.

FIG. 2 shows the information recorded by an identifying element in one embodiment of the present invention.

FIG. 3a to 3c are top views showing a chip mounting device according to another embodiment of the present invention.

FIG. 4 is a top view showing a chip mounting device according to still another embodiment of the present invention.

FIG. 5 is a top view showing a chip package array according to one embodiment of the present invention.

FIG. 6a is a sectional view showing a chip package array according to one embodiment of the present invention.

FIG. 6b is a sectional view showing a chip package array according to another embodiment of the present invention.

### DESCRIPTION OF THE PREFERRED EMBODIMENT

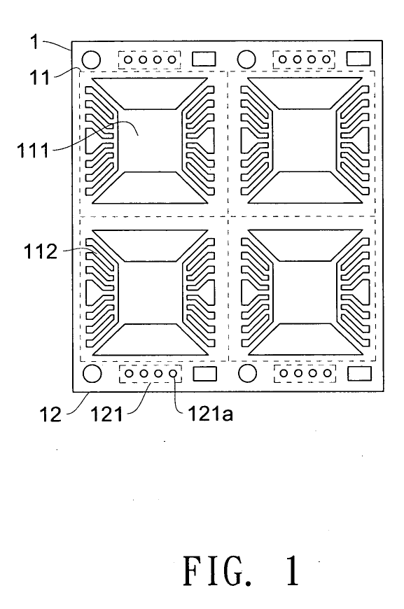

FIG. 1 shows a chip mounting device 1 according to a preferred embodiment of the present invention. The chip mounting device 1 includes a chip mount unit 11 and side rails 12. The chip mounting unit 11 includes a die pad 111 and a plurality of conductive contacts 112. The side rails 12 are configured beside the chip mount unit 11 and include identifying elements 121. In the embodiment shown in FIG. 1, the identifying element 121 is shown as at least one hole 121a. The hole 121a can be read and identified by an identifying sensor (not shown), e.g. an optical sensor or a mechanical sensor with probe.

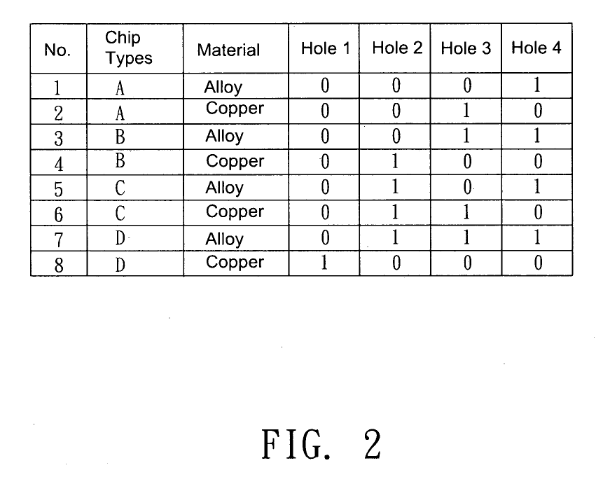

Referring to FIG. 2, according to a preferred embodiment of the present invention, the hole 121a for identification is binary encoded for recording information including the chip types, package process, and so on. For example, 1 means the forming hole 121a; and 0 means no forming of holes 121a. In the case chip A and alloy for the material of the chip mounting unit 11, the identifying code is 0001. In another case chip B and copper for the material of the chip mounting device 11, the identifying code is 0100. As a result, the formation of holes 121a configured at the relative position on the side rail 12 can be read by the identifying sensor for identification of relevant information.

The package process information relates to the information about the material of chip packing device in this embodiment. But it is not thus limited, the package process information also relates to other package process information, e.g. chip types and molding process.

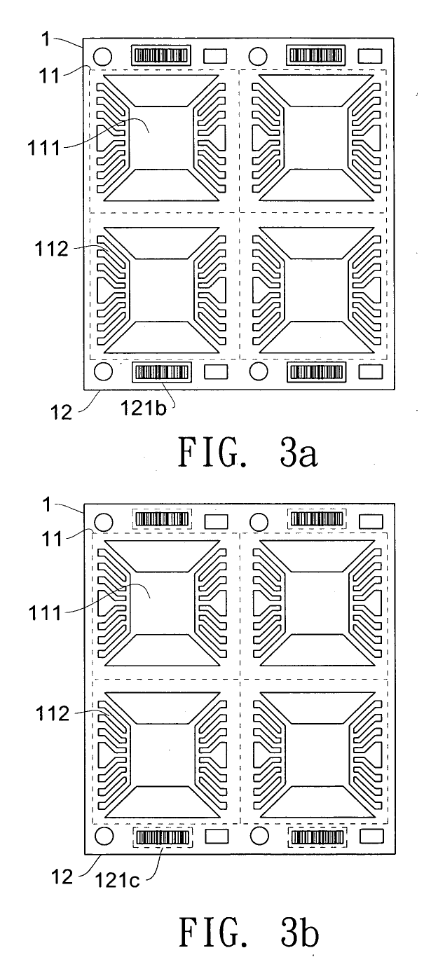

Referring to FIG. 3a to 3c, in another embodiment of the present invention, the identifying elements 121 may be a tag 121b, a mark 121c, or a notch 121d, and the above-mentioned identifying elements can be read and identified by associated sensor. For example, the tag 121b and mark 121c may include a bar code and be read and identified by a bar code reader.

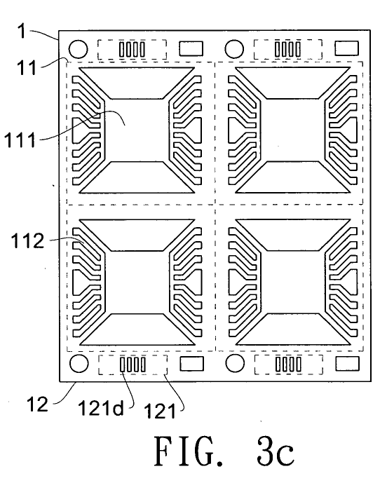

Referring to FIG. 1a again, in this embodiment, the chip mounting device 11 is a leadframe, and the leadframe includes a plurality of leads 112a as the conductive contacts 112 and configured beside die pad 111. Referring to FIG. 4, in another embodiment, the chip mounting device 11 is a package substrate, and the package substrate includes a plurality of bonding pads 112b on the surface as the conductive contacts 112. In this embodiment, the bonding pads 112b are configured on the die pad 111, and the package substrate may be a soft substrate, a hard substrate or a composite substrate.

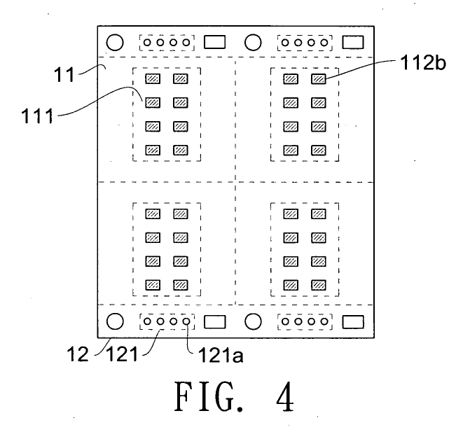

FIG. 5 shows a chip package array 3 according to a preferred embodiment of the present invention. The package array 3 includes a chip mounting device 1 and a chip 31, whereas the chip mounting device 1 has been described in the embodiment shown in FIG. 1 and the detailed description would be omitted. The chip 31 is mounted on the die pad 111 and electrically connected to the conductive contacts 112.

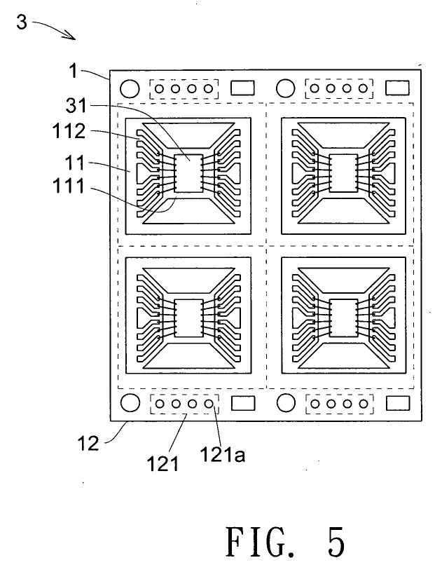

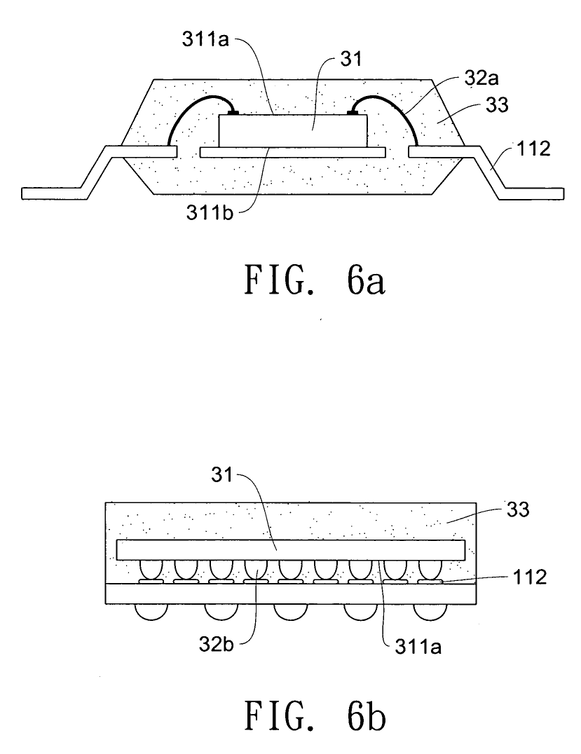

Referring to FIG. 6a, in one embodiment, the chip package array 3 further includes a plurality of wires 32a and molding compound 33. The chip 31 includes an active surface 311a and a back surface 311b opposite to the active surface 311a. The chip 31 is mounted onto the chip mounting unit 11 with the back surface 311b, and the wires 32a are electrically connected to the active surface 31 la of the chip 31 and the conductive contacts 112. The chip 31, wires 32a, and conductive contacts 112 are encapsulated with the molding compound 33.

Referring to FIG. 6b, in another embodiment, the chip package array 3 further includes a plurality of conductive bumps 32b an a molding compound 33. The chip 31 is mounted onto the chip mounting unit 11 with the active surface 311a, and the conductive bumps 32b are electrically connected to the active surface 311a of the chip and conductive contacts 112. The chip 31, conductive bumps 32b, and conductive contacts 112 are encapsulated with the molding compound 33.

Some possible application for the identification of the chip mounting device 1 and chip package array 3 is herein disclosed. In one embodiment, an identifying sensor may be installed to a feed machine in molding process for automatic identification of chip package arrays 3, and chip package arrays 3 may be delivered automatically based on the identified information. In another embodiment, after the molding process, the identifying element 121 on the chip package array 3 may be read for identification of information about the chip types and package process of chip package array 3.

To sum up, the chip mounting device and chip package array of the present invention includes an identifying element configured on the side rail for identifying sensor to read and identify the information about chip types and/or package process; therefore the identification of the chip mounting device and chip package array is improved, and the loss caused by misjudgments of operators is decreased.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A chip mounting device, comprising:
at least one chip mounting unit comprising a die pad and a plurality of conductive contacts; and
at least one side rail configured beside said chip mounting unit and arranging at least one identifying element thereon.

2. The chip mounting device as claimed in claim 1, wherein said identifying element is read by an identifying sensor.

3. The chip mounting device according to claim 1, wherein said identifying element comprises at least one hole.

4. The chip mounting device according to claim 3, wherein said identifying element is binary encoded.

5. The chip mounting device according to claim 1, wherein said identifying element comprises a tag, a mark, or a notch.

6. The chip mounting device according to claim 1, wherein said identifying element records information about chip types or package process.

7. The chip mounting device according to claim 1, wherein said chip mounting device is a leadframe arranging a plurality of leads as said conductive contacts.

8. The chip mounting device according to claim 1, wherein said chip mounting device is a package substrate arranging a plurality of bonding pads thereon as said conductive contacts.

9. The chip mounting device according to claim 8, wherein said package substrate is selected from a group consisted of a soft substrate, a hard substrate and a composite substrate.

10. A chip package array, comprising:
a chip mounting device, comprising:
at least one chip mounting unit comprising a die pad and a plurality of conductive contacts; and
at least one side rail configured beside said chip mounting unit and arranging at least one identifying element thereon; and
at least one chip mounted on said die pad and electrically connected to said conductive contacts.

11. The chip package array according to claim 10, wherein said identifying element is read by an identifying sensor.

12. The chip package array according to claim 10, wherein said identifying element comprises at least one hole.

13. The chip package array according to claim 12, wherein said identifying element is binary encoded.

14. The chip package array according to claim 10, wherein said identifying element comprises a tag, a mark, or a notch.

15. The chip package array according to claim 10, wherein said identifying element records information about chip types or package process.

16. The chip package array according to claim 10, wherein said chip mounting device is a leadframe arranging a plurality of leads as said conductive contacts.

17. The chip package array according to claim 10, wherein said chip mounting device is a package substrate arranging a plurality of bonding pads thereon as said conductive contacts.

18. The chip package array as claimed in claim 10, wherein said package substrate is selected from a group consisted of a soft substrate, a hard substrate and a composite substrate.

19. The chip package array according to claim 10, further comprising a plurality of wires, wherein said chip comprises an active surface and a back surface opposite to said active surface, said chip is mounted onto said chip mounting unit with said back surface, and said wires are electrically connected to said active surface of said chip and said conductive contacts.

20. said chip package array according to claim 19, further comprising a molding compound covering said chip, said wires, and said conductive contacts.

21. The chip package array according to claim 10, further comprising a plurality of conductive bumps, wherein said chip comprises an active surface and a back surface opposite to said active surface, said chip is mounted onto said chip package unit with said active surface, and said conductive bumps are electrically connected to said active surface of said chip and said conductive contacts.

22. The chip package array according to claim 21, further comprising a molding compound covering said chip, said wires, and said conductive contacts.
